(19) United States
(12) Patent Application Publication
(10) Pub. No.: US 2026/0094113 A1
(43) Pub. Date: Apr. 2, 2026

(54) BATTERY HEALTH MANAGEMENT

(71) Applicant: MOTOROLA SOLUTIONS, INC., Chicago, IL (US)

(72) Inventors: Chia Yi Quah, Sungai Petani (MY); Yih Farn Ghee, Alor Setar (MY); Chew How Lim, Bayan Lepas (MY); Yoke May Ling, Bayan Lepas (MY); Sin Yew Loh, Butterworth (MY); Ren Haw Tham, Tanjung Bungah (MY); Cheah Min Wong, Bayan Lepas (MY)

(21) Appl. No.: 18/902,512

(22) Filed: Sep. 30, 2024

(51) Int. Cl. G06Q 10/087; G01R 31/367; G01R 31/371; G01R 31/3828; G01R 31/392; H01M 10/44

(52) U.S. Cl. CPC G06Q 10/087; G01R 31/367; G01R 31/371; G01R 31/3828; G01R 31/392; H01M 10/44

(57) ABSTRACT

A system including an electronic processor that is configured to receive identifying information for a battery, retrieve, from a database, data regarding the battery and, when a date when a most recent state of charge (SOC) included in the data or a most recent integrated current accumulator (ICA) included in the data was determined is less than one month ago, determine a current SOC to be the most recent SOC or the current ICA to be a most recent ICA. The electronic processor is also configured to, when the data does not include the most recent SOC or ICA or when the date when the most recent SOC or ICA was determined is at least one month ago, estimate the current SOC or ICA and, in response to determining the current SOC or the current ICA of the battery is equal to 0, automatically charge the battery.

### BACKGROUND

Lithium-ion chemical cells included in lithium-ion batteries degrade over the life span of the battery. A typical lithium-ion battery experiences a 20-30 percent decrease in capacity over 500 charge/discharge cycles. The degradation rate (the rate at which the capacity of the battery decreases) depends on the charge/discharge cycles (for example, whether the battery is completely discharged before being recharged), a temperature the battery is stored at, a temperature of the battery when the battery is in use, and the like. A battery's health or state of health may refer to the battery's current full charged capacity compared to the battery's initial full charged capacity.

Additionally, batteries may be designed with internal protection and battery management circuitry that drains minor leakage current from the cells constantly. However, a deep discharge can compromise the long term performance of the battery cells. Therefore, a “boost” charge is required for the batteries every 9-12 months to prevent a deep discharge while they are stored.

### BRIEF DESCRIPTION OF THE SEVERAL VIEWS OF THE DRAWINGS

In the accompanying figures similar or the same reference numerals may be repeated to indicate corresponding or analogous elements. These figures, together with the detailed description, below are incorporated in and form part of the specification and serve to further illustrate various implementations, examples, aspects, and features of concepts that include the claimed subject matter, and to explain various principles and advantages of those implementations, examples, aspects, and features.

FIG. 1 is a block diagram of an example battery health management system, in accordance with some implementations.

FIG. 2 is a block diagram of an example computing device of the battery health management system of FIG. 1, in accordance with some implementations.

FIGS. 3A-3C are an example flowchart of a method for battery health management, in accordance with some implementations.

FIG. 4 is an example of a label attached to a battery included in the battery health management system of FIG. 1, in accordance with some implementations.

FIG. 5 is an example of a display device of the computing device of FIG. 2 displaying an indication of battery health, in accordance with some implementations.

FIG. 6 is an example list of batteries and an indication of their health that may be displayed via a display device of the computing device of FIG. 2, in accordance with some implementations.

Skilled artisans will appreciate that elements in the figures are illustrated for simplicity and clarity and have not necessarily been drawn to scale. For example, the dimensions of some of the elements in the figures may be exaggerated relative to other elements to help improve understanding of the examples, aspects, and features presented in this disclosure.

The system, apparatus, and method components have been represented where appropriate by conventional symbols in the drawings, showing only those specific details that are pertinent to understanding of the various implementations, examples, aspects, and features of the present disclosure so as not to obscure the disclosure with details that will be readily apparent to those of ordinary skill in the art having the benefit of the description herein.

### DETAILED DESCRIPTION OF THE INVENTION

After they are manufactured, batteries may be shipped to a distribution center. From the distribution center batteries may be shipped to end users. End users and personnel at distribution centers may have a large number of batteries that need to be accurately assessed, managed, and tracked. For example, when batteries are shipped from the factory, the batteries are often at a reduced state of charge. In some cases, batteries are at a less than 30% state of charge (SOC) to comply with the International Air Transport Association (IATA) air shipping regulations. A “boost” charge is required for the batteries every 9-12 months to prevent a deep discharge while they are stored. A deep discharge can compromise the long term performance of the battery cells. Additionally, batteries whose health has degraded beyond a certain measure should be replaced.

It is challenging for the end users or distribution center personnel to identify which batteries need to be replaced due to degraded health and which batteries need a boost charge to prevent deep discharge. For example, batteries may not be visible to users or distribution center personnel because the batteries are placed in boxes. Used batteries may be placed together in large containers, scattered, or disorganized.

Thus, there exists a need for an improved technical method, device, and system for battery health management. The implementations described herein allow batteries to be easily identified using a camera, a bar code scanner, a quick response (QR) code scanner, an RFID scanner, a combination of the foregoing, or the like. Once a battery is identified, information included in a battery management system database may be utilized to determine whether the battery needs a boost charge or needs to be replaced.

One example provides, a system for managing battery health. The system includes an electronic processor. The electronic processor is configured to receive identifying information for a battery, retrieve, from a database, data regarding the battery, and determine whether the data includes a most recent state of charge or a most recent integrated current accumulator of the battery. The electronic processor is also configured to, when the data includes the most recent state of charge or the most recent integrated current accumulator of the battery, determine whether a date when the most recent state of charge or the most recent integrated current accumulator of the battery was determined is less than one month ago. The electronic processor is further configured to, when the date when the most recent state of charge or the most recent integrated current accumulator was determined is less than one month ago, determine a current state of charge to be the most recent state of charge or a current integrated current accumulator to be the most recent integrated current accumulator. The electronic processor is also configured to, when the data does not include the most recent state of charge or the most recent integrated current accumulator of the battery or when the date when the most recent state of charge or integrated current accumulator was determined is at least one month ago, estimate the current state of charge of the battery or the integrated current accumulator based on a date of manufacture of the battery or the date when the most recent state of charge or the most recent integrated current accumulator of the battery was determined. The electronic processor is further configured to determine whether the current state of charge or the current integrated current accumulator of the battery is equal to 0, and, in response to determining the current state of charge or the current integrated current accumulator of the battery is equal to 0, automatically charge the battery.

Another example provides, a method for managing battery health. The method includes receiving identifying information for a battery, retrieving, from a database, data regarding the battery, and determining whether the data includes a most recent state of charge or a most recent integrated current accumulator of the battery. The method also includes, when the data includes the most recent state of charge or the most recent integrated current accumulator of the battery, determining whether a date when the most recent state of charge or the most recent integrated current accumulator of the battery was determined is less than one month ago. The method further includes, when the date when the most recent state of charge or the most recent integrated current accumulator was determined is less than one month ago, determining a current state of charge to be the most recent state of charge or a current integrated current accumulator to be the most recent integrated current accumulator. The method also includes, when the data does not include the most recent state of charge or the most recent integrated current accumulator of the battery or when the date when the most recent state of charge or integrated current accumulator was determined is at least one month ago, estimating the current state of charge of the battery or the integrated current accumulator based on a date of manufacture of the battery or the date when the most recent state of charge or the most recent integrated current accumulator of the battery was determined. The method further includes, determining whether the current state of charge or the current integrated current accumulator of the battery is equal to 0, and, in response to determining the current state of charge or the current integrated current accumulator of the battery is equal to 0, automatically charging the battery.

Each of the above-mentioned examples will be discussed in more detail below, starting with example system and device architectures of the system in which the examples may be practiced, followed by an illustration of processing blocks for achieving an improved technical method, device, and system for battery health management.

Examples are herein described with reference to flowchart illustrations and/or block diagrams of methods, apparatus (systems) and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a special purpose and unique machine, such that the instructions, which execute via the processor of the computer or other programmable data processing apparatus, create means for implementing the functions/acts specified in the flowchart and/or block diagram block or blocks. The methods and processes set forth herein need not, in some aspects, be performed in the exact sequence as shown and likewise various blocks may be performed in parallel rather than in sequence. Accordingly, the elements of methods and processes are referred to herein as “blocks” rather than “steps.”

Computer program instructions may also be stored in a computer-readable memory that can direct a computer or other programmable data processing apparatus to function in a particular manner, such that the instructions stored in the computer-readable memory produce an article of manufacture including instructions which implement the function/act specified in the flowchart and/or block diagram block or blocks.

The computer program instructions may also be loaded onto a computer or other programmable data processing apparatus that may be on or off-premises, or may be accessed via the cloud in any of a software as a service (SaaS), platform as a service (PaaS), or infrastructure as a service (IaaS) architecture so as to cause a series of operational blocks to be performed on the computer or other programmable apparatus to produce a computer implemented process such that the instructions which execute on the computer or other programmable apparatus provide blocks for implementing the functions/acts specified in the flowchart and/or block diagram block or blocks. It is contemplated that any part of any example, feature, aspect, or implementation discussed in this specification can be implemented or combined with any part of any other example, feature, aspect, or implementation discussed in this specification.

Further advantages and features consistent with this disclosure will be set forth in the following detailed description, with reference to the figures.

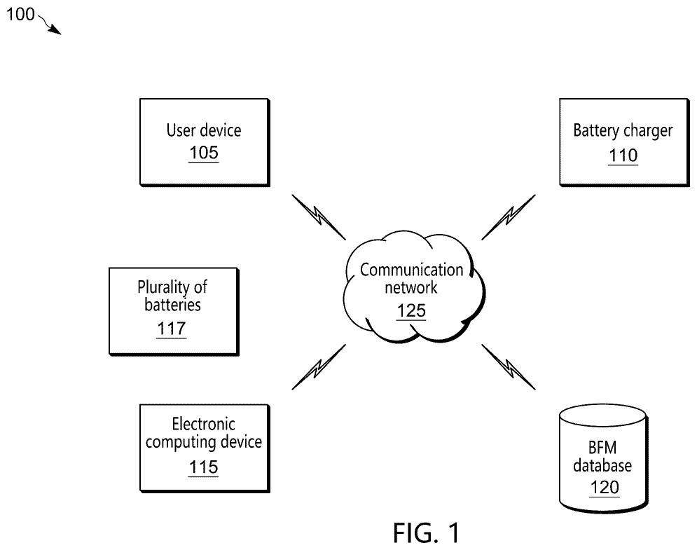

Referring now to the drawings, FIG. 1 illustrates an example system 100 for battery health management. In some implementations, the system 100 includes a user device 105, a battery charger 110, an electronic computing device 115, a plurality of batteries 117, and a battery fleet management (BFM) database 120. In some implementations the user device 105, battery charger 110, electronic computing device 115, and BFM database 120 communicate via the communication network 125.

The communication network 125 may be implemented using wired or wireless communication components and may include various networks, for example, a wide area network, such as the Internet, a Long Term Evolution (LTE) network, a Global System for Mobile Communications (or Groupe Spécial Mobile (GSM)) network, a Code Division Multiple Access (CDMA) network, an Evolution-Data Optimized (EV-DO) network, an Enhanced Data Rates for GSM Evolution (EDGE) network, a 3G network, a 4G network, a 5G network, a local area network (for example a Wi-Fi™ network or an Ethernet network), and combinations or derivatives thereof.

In some implementations, the user device 105 is configured to receive power from one or more batteries of the plurality of batteries 117. For example, the user device 105 may be a radio (for example, a portable radio device, a mobile radio device, a dispatcher console, or the like). In some implementations, the battery charger 110 is configured to charge one or more batteries of the plurality of batteries 117. In some implementations, each battery included in the plurality of batteries 117 includes a memory storing data regarding the battery. While the batteries included in the plurality of batteries 117 are not capable of communicating with the BFM database 120 via the communication network 125, when a battery of the plurality of batteries 117 is charged via the battery charger 110 or is connected to the user device 105, the battery charger 110, the user device 105, or both may provide data regarding the battery to the BFM database 120. The BFM database 120 may be included in a BFM system. The BFM system may include one or more servers and/or databases (including, for example, the BFM database 120) configured to store data regarding the plurality or fleet of batteries 117.

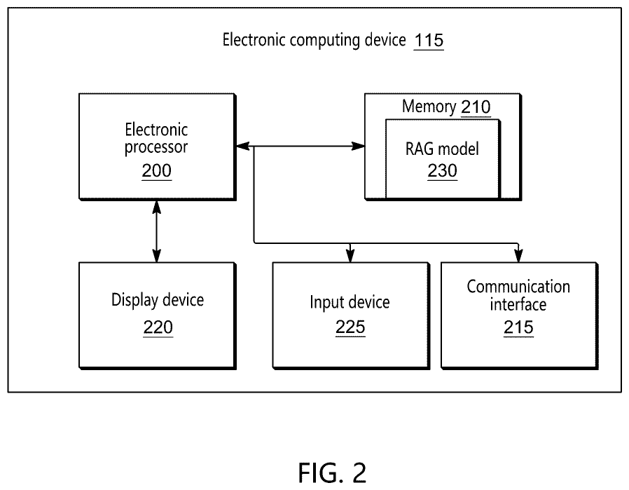

FIG. 2 provides a block diagram of an example electronic computing device 115. In the example provided, the electronic computing device 115 includes an electronic processor 200, a memory 210, a communication interface 215, a display device 220, and an input device 225. The illustrated components, along with other various modules and components (not shown) are coupled to each other by or through one or more control or data buses that enable communication therebetween. The use of control and data buses for the interconnection between and exchange of information among the various modules and components would be apparent to a person skilled in the art in view of the description provided herein.

The electronic processor 200 obtains and provides information (for example, from the memory 210, input device 225, and/or the communication interface 215), and processes the information by executing one or more software instructions or modules, capable of being stored, for example, in a random access memory (“RAM”) area of the memory 210 or a read only memory (“ROM”) of the memory 210 or another non-transitory computer readable medium (not shown). The software can include firmware, one or more applications, program data, filters, rules, one or more program modules, and other executable instructions. The electronic processor 200 is configured to retrieve from the memory 210 and execute, among other things, software related to the methods described herein.

The memory 210 can include one or more non-transitory computer-readable media and includes a program storage area and a data storage area. The program storage area and the data storage area can include combinations of different types of memory, as described herein. In the implementation illustrated, the memory 210 stores, among other things, a retrieval augmented generation (RAG) model 230.

The communication interface 215 is configured to receive input and to provide system output. The communication interface 215 obtains information and signals from, and provides information and signals to, (for example, over one or more wired and/or wireless connections) devices both internal and external to the electronic computing device 115. The communication interface 215 may include a wireless transmitter or transceiver for wirelessly communicating over the communication network 125. Alternatively, or in addition to a wireless transmitter or transceiver, the communication interface 215 may include a port for receiving a cable, such as an Ethernet cable, for communicating over the communication network 125 or a dedicated wired connection. In some implementations, the electronic computing device 115 communicates with other devices through one or more intermediary devices, such as routers, gateways, relays, and the like.

In the implementation illustrated, the electronic computing device 115 includes a display device 220, which is a suitable display such as, for example, a liquid crystal display (LCD) touch screen, or an organic light-emitting diode (OLED) touch screen. In some implementations, the electronic computing device 115 implements a graphical user interface (GUI) (for example, generated by the electronic processor 200, from instructions and data stored in the memory 210, and presented on the display device 220), that enables a user to interact with the electronic computing device 115.

While illustrated as including a single input device 225, the electronic computing device 115 may include multiple input devices. For example, the input device(s) 225 may include a camera, a RFID scanner, a bar code scanner, a QR code scanner, a microphone, a touch screen, one or more buttons, a combination of the foregoing, and the like.

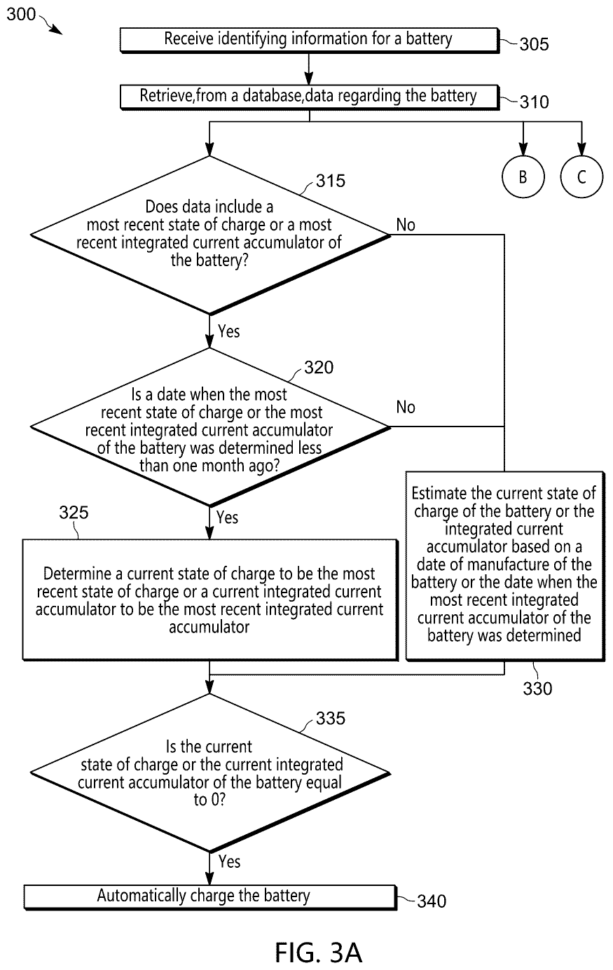

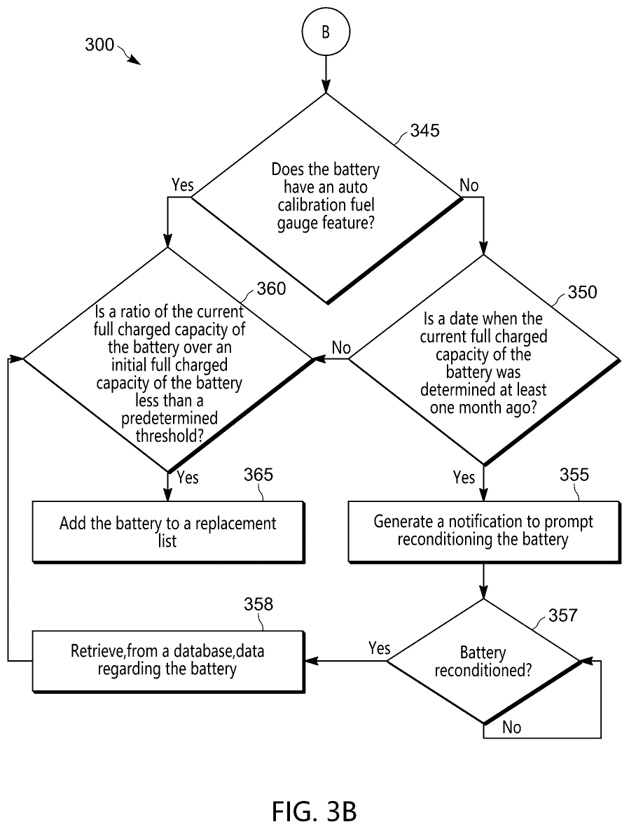

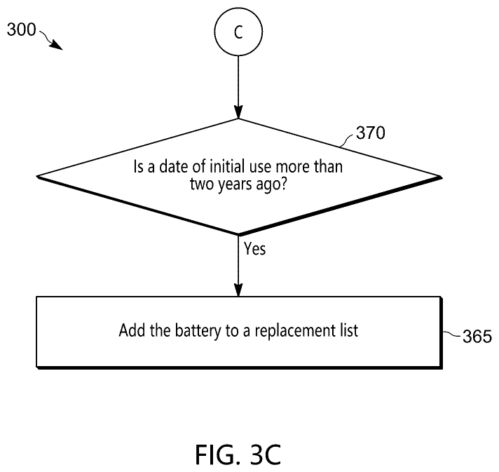

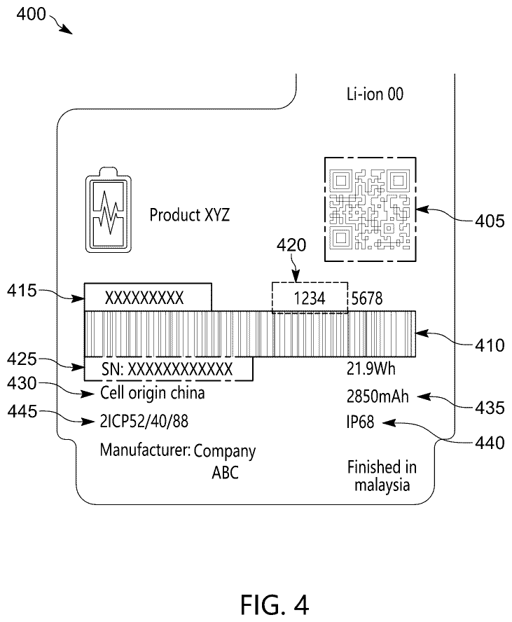

FIGS. 3A-3C illustrate an example flowchart of a method 300 for managing battery health. In some implementations, the method 300 begins at block 305, when the electronic processor 200 receives identifying information for a battery. In some implementations, receiving identifying information for a battery includes scanning or capturing an image of a label attached to the battery with a camera (for example, the input device 225). FIG. 4 includes an example of a label 400 that may be attached to the battery and scanned or captured using a camera of the electronic computing device 115. As illustrated in FIG. 4, the label 400 may include a QR code 405, a barcode 410, a kit number 415, a date code 420, a serial number 425, a cell origin 430, an initial battery capacity 435, an IP rating 440, and a combination of cells within the battery pack 445. The label illustrated in FIG. 4 is an example, and other labels including more information, less information, or different information may be attached to the battery and scanned by the input device 225. For example, a label attached to a battery may include a bar code or a QR code rather than both. In some implementations, the electronic processor 200 utilizes optical character recognition (OCR) techniques to identify and extract information included in the label 400. In some implementations, a bar code scanner included in the electronic computing device 115 may be used to scan the bar code. In some implementations, a QR code scanner included in the electronic computing device 115 may be used to scan the QR code.

Additionality or alternatively, receiving identifying information for a battery includes scanning an RFID tag included in or attached to the battery. In some implementations, the RFID tag includes a unique serial number that identifies the battery. Using an RFID scanner to obtain battery information allows identifying information to be easily received for a plurality of batteries with labels that may not be visible (within the field of view of a camera of the electronic computing device 115). For example, the RFID scanner may be used to retrieve battery information for batteries that are in boxes or packaging or are stacked on top of one another.

At block 310, the electronic processor 200 retrieves, from a database (for example, the BFM database 120), data regarding the battery. In some implementations, retrieving, from a database, data regarding the battery includes the electronic processor 200 sending to the BFM database 120, information identifying the battery. In response to receiving the information identifying the battery, the BFM database 120 sends to the electronic processor 200 data regarding the battery. The data regarding the battery may include the date of manufacture, a date of initial use, the most recent state of charge, a full charged capacity, an initial full charged capacity, an integrated current accumulator (ICA), a first day self-discharge percentage, and a subsequent day self-discharge percentage.

In some implementations, at block 315, the electronic processor 200 determines whether the data includes a most recent state of charge or a most recent ICA of the battery.

In some implementations, when the data includes the most recent state of charge or the most recent ICA of the battery, at block 320, the electronic processor 200 determines whether a date when a most recent state of charge or a most recent ICA of the battery was determined is less than one month ago. When the date when the most recent state of charge or the most recent ICA was determined is less than one month ago, at block 325, the electronic processor 200 determines a current state of charge to be the most recent state of charge or a current ICA to be the most recent ICA.

At block 330, when the data does not include the most recent state of charge or the most recent ICA of the battery or when the date when the most recent state of charge or ICA was determined is at least one month ago, the electronic processor 200 estimates the current state of charge of the battery or the current ICA based on a date of manufacture of the battery or the date when a most recent state of charge or a most recent ICA of the battery was determined. In some implementations, when the data includes the most recent state of charge or the most recent ICA of the battery but the date when the most recent state of charge or ICA was determined is at least one month ago, the electronic processor 200 uses programming implementing Equation 1 to estimate the current ICA.

$$Current ICA = ( most recent ICA ) - ( first day self - discharge rate ) - ( number of days since the date when the most recent ICA of the battery was determined * subsequent days self - discharge rate ) \qquad Equation 1$$

In Equation 1, the first day self-discharge rate is the amount of charge that the battery loses the first day after the battery is charged. In Equation 1, the subsequent days self-discharge rate is the amount of charge that the battery loses each day after the first day after the battery is charged. In some implementations, ICA is measured in milliamps (mAh). In some implementations, the first day self-charge rate is a first day self-discharge percentage multiplied by the current capacity of the battery. In some implementations, the subsequent day self-charge rate is a subsequent day self-discharge percentage multiplied by the current capacity of the battery.

In some implementations, when the data includes the most recent state of charge or the most recent ICA of the battery, the electronic processor 200 uses programming implementing Equation 2 to estimate the current ICA.

$$Current ICA = ( 25 \% \times current full charge capacity of battery ) - ( first day self - discharge rate ) - ( number of days since the date of manufacture of the battery * subsequent days self - discharge rate ) \qquad Equation 2$$

For example, assuming the battery is a fresh battery with current a state of charge of 25%, when the current full charge capacity of the battery is 5,000 mAh, the first day self-discharge percentage is 0.5% per day, the subsequent days self-discharge percentage is 0.2% per day, the first day self-discharge rate=(0.5%×5,000)=25 mAh per day and the subsequent day discharge rate=(0.1%×5,000)=5 mAh per day. Therefore, assuming 90 days have passed since the battery was manufactured, the current ICA=(25%×5,000 mAh)−(25 mAh)−(90*5 mAh)=775 mAh. In some implementations, in Equation 2, 25 percent represents the less than 30 percent state of charge that batteries are shipped at to comply with IATA regulations.

As shown in Equation 3, the electronic processor 200 may estimate a current state of charge of the battery based on the current ICA.

$$Current state of charge of the battery = current ICA of the battery / current full charge capacity of battery \qquad Equation 3$$

Therefore, when the current ICA of the battery is 775 mAh and the current full charge capacity of the battery is 5,000 mAh, the current state of charge of the battery=775 mAh/5,000 mAh=15.5%.

At block 335, the electronic processor 200 determines whether the current state of charge or the current ICA of the battery is equal to 0. At block 340, in response to determining the current state of charge or the current ICA of the battery is equal to 0, the electronic processor 200 automatically charges the battery.

In some implementations, in addition to or instead of automatically charging the battery, the electronic processor 200 generates an alert to charge the battery. The alert may be aural, visual, haptic, or a combination of the foregoing. In some implementations, the alert may include a notification that is generated by the electronic processor 200 for display via the display device 220. In some implementations, the alert may include an aural notification that is output via a speaker (not illustrated) included in the electronic computing device 115.

Referring now to FIG. 3B, in some implementations, at block 345, the electronic processor 200 determines whether the battery has an auto calibration fuel gauge feature.

Batteries that include the auto calibration fuel gauge feature perform a long duration reconditioning process monthly. Batteries that include the auto calibration fuel gauge feature also automatically calibrate the capacity of the battery based on battery usage conditions. At block 350, in response to determining that the battery does not have an auto calibration fuel gauge feature, the electronic processor 200 determines whether a date when the current full charge capacity of the battery was determined was at least one month ago. When the current full charge capacity of the battery was determined at least one month ago, at block 355, the electronic processor 200 generates a notification to prompt reconditioning the battery. In some implementations, the notification that is generated by the electronic processor 200 is displayed via the display device 220. In some implementations, the notification may be an aural notification that is output via a speaker (not illustrated) included in the electronic computing device 115. In some implementations, the electronic processor 200 automatically reconditions the battery. Reconditioning the battery may include discharging the battery to a termination voltage and fully recharging the battery.

In some implementations, the electronic processor 200, after generating the notification to prompt reconditioning of the battery, determines, at block 357, whether the battery has been reconditioned. For example, in some implementations, the electronic processor 200 receives input from a user indicating a battery has been reconditioned. In response to determining that the battery has been reconditioned, the electronic processor 200 may retrieve, from the database, data regarding the battery at block 358. The data retrieved at block 358 may contain a current full charged capacity that was determined when the battery was reconfigured. In some implementations, the electronic processor 200 performs block 358 prior to performing block 357. In such implementations, the electronic processor 200 may determine whether the battery has been reconditioned based on the date when the current full charged capacity is determined. For example, when the date when the current full charged capacity is determined is updated (is more recent than the date previously retrieved), the electronic processor 200 may determine, at block 357, that the battery has been reconditioned. When the electronic processor 200, determines, at block 357, the battery has not been reconditioned, the electronic processor 200 may return to block 358 and re-retrieve, from the database, the data regarding the battery after a predetermined amount of time (for example, hour).

After performing the functionality described in relation to block 357 and 358, the electronic processor 200 proceeds to determine whether a ratio of the current full charged capacity of the battery (obtained at block 358) over an initial full charged capacity of the battery is less than a predetermined threshold at block 360. The ratio of the current full charged capacity of the battery over an initial full charged capacity of the battery may be referred to as the state of health of the battery. In some implementations, when the electronic processor 200 determines, at block 345, that the battery has an auto calibration fuel gauge feature, the electronic processor 200 proceeds to determine whether the state of health of the battery is less than a predetermined threshold at block 360. In some implementations, the predetermined threshold is 0.6 or 60 percent. When the electronic processor 200 determines that state of health of the battery is less than the predetermined threshold, the electronic processor 200 adds the battery to a replacement list or a reorder report. In some implementations, when the state of health of the battery is less than the predetermined threshold, the electronic processor 200 generates an alert prompting replacement of the battery.

In some implementations, prior to performing the functionality described in relation to block 345, the electronic processor 200 determined whether a date of initial use is a date prior to the current date. In some implementations, when the date of initial use is a date prior to the current date, the electronic processor 200 proceeds to perform the functionality described in relation to FIG. 3B. When the date of initial use is not a date prior to the current date (the battery has not yet charged or discharged by a charger or user device), the electronic processor 200 does not perform the functionality described in relation to FIG. 3B.

Referring now to FIG. 3C, in some implementations, at block 370, the electronic processor 200 determines whether a date of initial use was more than two years ago. In some implementations, the date of initial use is a date is a date when the battery is first discharged by a user device (for example, the user device 105) or charged by a battery charger (for example, the battery charger 110). In some implementations, at block 365, in response to determining the date of initial use was more than two years ago, the electronic processor 200 adds the battery to the replacement list or reorder report. In some implementations, when the date of initial use was more than two years ago, the electronic processor 200 generates an alert prompting replacement of the battery.

In some implementations, the electronic processor 200 generates an indication of the health of the battery. The electronic processor 200 may generate the indication of the health of the battery based on the ratio described in relation to block 360 of FIG. 3B.

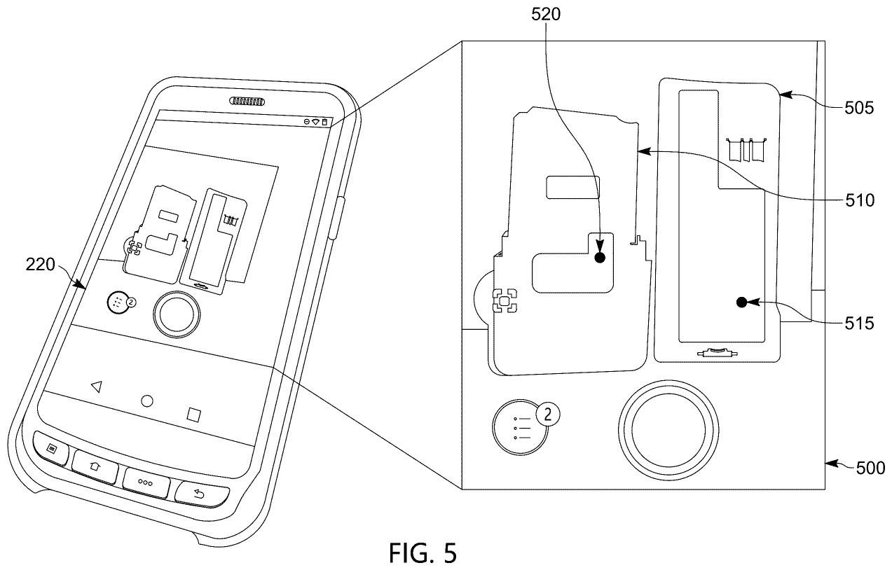

In some implementations, the electronic processor 200 generates the indication of the health of the battery by receiving an image of the battery from a camera, displaying the image of the battery on a display device, and generating, in the image, the indication in augmented reality. For example, the electronic processor 200 overlays the indication on the battery in the image displayed via the display device 220. FIG. 5 provides an example of an indication of a state of health of a battery. As shown in FIG. 5, the display device 220 displays an image 500 of the batteries 505, 510. The indicators 515, 520 indicate the health of the batteries 505, 510. In some implementations, the color of the indicator indicates the state of health of the battery that the indicator is associated with. For example, when the indicator is red, the state of health of the battery is less than the predetermined threshold. When the indicator is green, the state of health of the battery may be greater than or equal to the predetermined threshold.

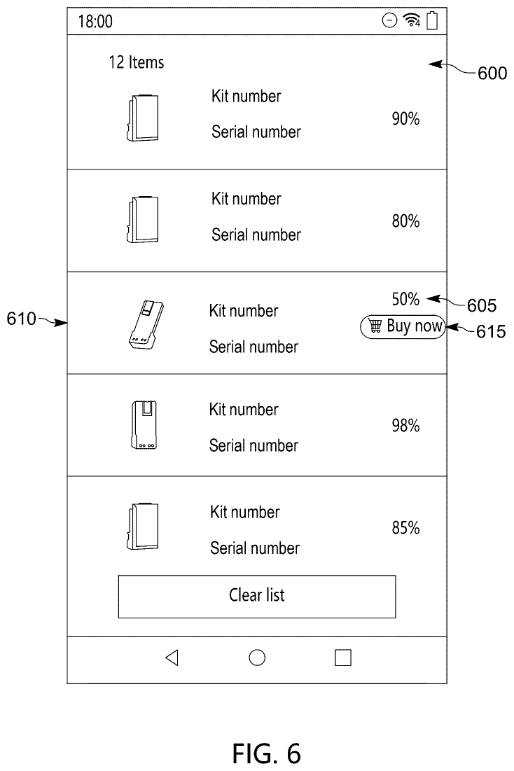

While displaying the indication of the battery health in augmented reality may be appropriate when a camera of the electronic computing device 115 is used to capture identifying information for the battery, when, for example, an RFID scanner is used to capture information for a battery, the electronic processor 200 may display a list of batteries whose information is captured by the RFID scanner. FIG. 6 is an example of a list 600 of batteries that may be displayed via the display device 220 of the electronic computing device 115. As illustrated in FIG. 6, each battery included in the list 600 is associated with a percentage that is indicative of the health of the battery. For example, the percentage may be the ratio described above in relation to block 360. In some implementations, the color of the text of the percentage indicates whether the percentage is above or below the predetermined threshold described in relation to block 360. For example, when the text of the percentage is displayed in red, the percentage is less than the predetermined threshold and, when the text of the percentage is displayed in green, the percentage is greater than or equal to the predetermined threshold. In some implementations, when a percentage 605 associated with a battery 610 is below the predetermined threshold, the electronic processor 200, displays a graphical user interface (GUI) button 615 below the displayed percentage 605. In some implementations, when a selection of the GUI button 615 is received, an interface that allows a replacement battery to be ordered is displayed by the electronic processor 200.

In some implementations, the electronic processor 200 receives a natural language query regarding the battery. The natural language query may be received by the input device 225 (for example, a touch screen or a microphone). In response to receiving the query, the electronic processor 200 generates a natural language output using, in one example, a retrieval augmented generation (RAG) model. In some implementations, the electronic processor 200, executing the RAG model, generates the natural language output based on the natural language query and documentation regarding the battery retrieved from the BFM database 120. In some implementations, the natural language output is displayed via the display device 220.

As should be apparent from this detailed description above, the operations and functions of the electronic computing device are sufficiently complex as to require their implementation on a computer system, and cannot be performed, as a practical matter, in the human mind. Electronic computing devices such as set forth herein are understood as requiring and providing speed and accuracy and complexity management that are not obtainable by human mental steps, in addition to the inherently digital nature of such operations (e.g., a human mind cannot interface directly with RAM or other digital storage, cannot transmit or receive electronic messages, electronically encoded video, electronically encoded audio, etc., and cannot automatically charge a battery or generate a notification for display in augmented reality, among other features and functions set forth herein).

In the foregoing specification, specific implementations, examples, aspects, and features have been described. However, one of ordinary skill in the art appreciates that various modifications and changes can be made without departing from the scope of the subject matter as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing,” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if implementations described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

It will be appreciated that some implementations, examples, aspects, and features may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, one or more of the implementations, examples, aspects, and features presented herein can be implemented as a computer-readable storage medium having computer readable code stored thereon for programming a computer (e.g., comprising a processor) to perform a method as described and claimed herein. Any suitable computer-usable or computer readable medium may be utilized. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. In the context of this document, a computer-usable or computer-readable medium may be any medium that can contain, store, communicate, propagate, or transport the program for use by or in connection with the instruction execution system, apparatus, or device.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. For example, computer program code for carrying out operations of various example implementations may be written in an object oriented programming language such as Java, Smalltalk, C++, Python, or the like. However, the computer program code for carrying out operations of various example implementations may also be written in conventional procedural programming languages, such as the “C” programming language or similar programming languages. The program code may execute entirely on a computer, partly on the computer, as a stand-alone software package, partly on the computer and partly on a remote computer or server or entirely on the remote computer or server. In the latter scenario, the remote computer or server may be connected to the computer through a local area network (LAN) or a wide area network (WAN), or the connection may be made to an external computer (for example, through the Internet using an Internet Service Provider).

The terms “substantially,” “essentially,” “approximately,” “about,” or any other version thereof, are defined as being close to as understood by one of ordinary skill in the art, and in one non-limiting implementation the term is defined to be within 10%, in another implementation within 5%, in another implementation within 1% and in another implementation within 0.5%. The term “one of,” without a more limiting modifier such as “only one of,” and when applied herein to two or more subsequently defined options such as “one of A and B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled,” “coupling,” or “connected” as used herein can have several different meanings depending on the context in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples and implementations for the purpose of streamlining the disclosure. This method of disclosure is not to be interpreted as reflecting an intention that the claimed subject matter requires more features than are expressly recited in each claim. Rather, as the following claims reflect, inventive subject matter lies in less than all features of a single disclosed implementation. Thus the following claims are hereby incorporated into the Detailed Description, with each claim standing on its own as a separately claimed subject matter.

What is claimed is:

1. A system for managing battery health, the system comprising:
an electronic processor, the electronic processor configured to:
receive identifying information for a battery;
retrieve, from a database, data regarding the battery;
determine whether the data includes a most recent state of charge or a most recent integrated current accumulator of the battery;
when the data includes the most recent state of charge or the most recent integrated current accumulator of the battery, determine whether a date when the most recent state of charge or the most recent integrated current accumulator of the battery was determined is less than one month ago;
when the date when the most recent state of charge or the most recent integrated current accumulator was determined is less than one month ago, determine a current state of charge to be the most recent state of charge or a current integrated current accumulator to be the most recent integrated current accumulator;
when the data does not include the most recent state of charge or the most recent integrated current accumulator of the battery or when the date when the most recent state of charge or integrated current accumulator was determined is at least one month ago, estimate the current state of charge of the battery or the integrated current accumulator based on a date of manufacture of the battery or the date when the most recent state of charge or the most recent integrated current accumulator of the battery was determined;
determine whether the current state of charge or the current integrated current accumulator of the battery is equal to 0; and
in response to determining the current state of charge or the current integrated current accumulator of the battery is equal to 0, automatically charge the battery.

2. The system according to claim 1, wherein the data includes a current full charged capacity of the battery and an initial full charged capacity of the battery and the electronic processor is further configured to:
determine whether the battery has an auto calibration fuel gauge feature; and
in response to determining that the battery has the auto calibration fuel gauge feature,
determine whether a ratio of the current full charged capacity of the battery over the initial full charged capacity of the battery is less than a predetermined threshold; and
in response to determining the ratio is less than the predetermined threshold, add the battery to a replacement list.

3. The system according to claim 2, wherein the electronic processor is further configured to:
in response to determining that the battery does not have the auto calibration fuel gauge feature,
determine whether a date when the current full charged capacity of the battery was determined is at least one month ago;
in response to determining the date when the current full charged capacity of the battery was determined is at least one month ago, generate a notification to prompt reconditioning the battery;
in response to determining the date when the current full charged capacity of the battery was determined less than one month ago, determine whether the ratio of the current full charged capacity of the battery over the initial full charged capacity of the battery is less than the predetermined threshold; and
in response to determining the ratio is less than the predetermined threshold, add the battery to the replacement list.

4. The system according to claim 1, wherein the electronic processor is configured to receive the identifying information for the battery when at least one selected from the group consisting of a QR code, a barcode, and an RFID tag is scanned.

5. The system according to claim 1, wherein the electronic processor is further configured to:
receive an image of the battery from a camera;
display the image of the battery on a display device; and
generate, in the image, an indication of health of the battery in augmented reality, wherein the indication is overlaid on the battery in the image.

6. The system according to claim 1, wherein the electronic processor is further configured to:
receive a natural language query regarding the battery; and
generate a natural language output using a retrieval augmented generation model, wherein the natural language output is based on the natural language query and documentation regarding the battery retrieved from the database.

7. The system according to claim 1, wherein the database receives the data from a charger or a user device.

8. The system according to claim 1, wherein the data includes at least one selected from the group consisting of the date of manufacture, a date of initial use, the most recent state of charge, a current full charged capacity, an initial full charged capacity, the integrated current accumulator, a first day self-discharge percentage, and a subsequent day self-discharge percentage.

9. The system according to claim 1, wherein the data includes a date of initial use and the electronic processor is further configured to:
determine whether the date of initial use was more than two years ago; and
in response to determining the date of initial use was more than two years ago, add the battery to a replacement list.

10. A method for managing battery health, the method comprising:
receiving identifying information for a battery;
retrieving, from a database, data regarding the battery;
determining whether the data includes a most recent state of charge or a most recent integrated current accumulator of the battery;
when the data includes the most recent state of charge or the most recent integrated current accumulator of the battery, determining whether a date when the most recent state of charge or the most recent integrated current accumulator of the battery was determined is less than one month ago;
when the date when the most recent state of charge or the most recent integrated current accumulator was determined is less than one month ago, determining a current state of charge to be the most recent state of charge or a current integrated current accumulator to be the most recent integrated current accumulator;
when the data does not include the most recent state of charge or the most recent integrated current accumulator of the battery or when the date when the most recent state of charge or integrated current accumulator was determined is at least one month ago, estimating the current state of charge of the battery or the integrated current accumulator based on a date of manufacture of the battery or the date when the most recent state of charge or the most recent integrated current accumulator of the battery was determined;
determining whether the current state of charge or the current integrated current accumulator of the battery is equal to 0; and
in response to determining the current state of charge or the current integrated current accumulator of the battery is equal to 0, automatically charging the battery.

11. The method according to claim 10, wherein the data includes a current full charged capacity of the battery and an initial full charged capacity of the battery and the method further comprising:
determining whether the battery has an auto calibration fuel gauge feature; and
in response to determining that the battery has the auto calibration fuel gauge feature,
determining whether a ratio of the current full charged capacity of the battery over the initial full charged capacity of the battery is less than a predetermined threshold; and
in response to determining the ratio is less than the predetermined threshold, adding the battery to a replacement list.

12. The method according to claim 11, the method further comprising:
in response to determining that the battery does not have the auto calibration fuel gauge feature,
determining whether a date when the current full charged capacity of the battery was determined is at least one month ago;
in response to determining the date when the current full charged capacity of the battery was determined is at least one month ago, generating a notification to prompt reconditioning the battery;
in response to determining the date when the current full charged capacity of the battery was determined less than one month ago, determining whether the ratio of the current full charged capacity of the battery over the initial full charged capacity of the battery is less than the predetermined threshold; and
in response to determining the ratio is less than the predetermined threshold, adding the battery to the replacement list.

13. The method according to claim 10, wherein receiving identifying information for a battery includes:
receiving identifying information for the battery when at least one selected from the group consisting of a QR code, a barcode, and an RFID tag is scanned.

14. The method according to claim 10, the method further comprising:
receiving an image of the battery from a camera;
displaying the image of the battery on a display device; and
generating, in the image, an indication of health of the battery in augmented reality, wherein the indication is overlaid on the battery in the image.

15. The method according to claim 10, the method further comprising:
receiving a natural language query regarding the battery; and
generating a natural language output using a retrieval augmented generation model, wherein the natural language output is based on the natural language query and documentation regarding the battery retrieved from the database.

16. The method according to claim 10, wherein the database receives the data from a charger or a user device.

17. The method according to claim 10, wherein the data includes at least one selected from the group consisting of the date of manufacture, a date of initial use, the most recent state of charge, a current full charged capacity, an initial full charged capacity, the integrated current accumulator, a first day self-discharge percentage, and a subsequent day self-discharge percentage.

18. The method according to claim 10, wherein the data includes a date of initial use and the method further comprising:
determining whether the date of initial use was more than two years ago; and
in response to determining the date of initial use was more than two years ago, adding the battery to a replacement list.
